(19) United States
(12) Patent Application Publication
(10) Pub. No.: US 2026/0107810 A1
(43) Pub. Date: Apr. 16, 2026

(54) CHIP WARPAGE CONTROL METHOD IN LASER COMPRESSION BONDING PROCESS

(71) Applicant: MI EQUIPMENT (M) SDN. BHD., Bayan Lepas (MY)

(72) Inventors: Cheol Joo CHO, Incheon (KR); Sung Han LEE, Osan-si (KR); Hyeong Ju LEE, Gunpo-si (KR)

(21) Appl. No.: 19/357,239

(22) Filed: Oct. 14, 2025

(30) Foreign Application Priority Data
Oct. 15, 2024 (KR) 10-2024-0140563

(51) Int. Cl. H01L 23/00; B23K 26/20; H01L 21/67; B23K 101/40

(52) U.S. Cl. CPC H10W 72/0711; B23K 26/20; H10P 72/0446; B23K 2101/40; H10W 72/07141

(57) ABSTRACT

The present invention relates to a laser compression bonding process which adsorbs a semiconductor chip (C) with a bonding tool (10) to apply a flux to a bump on the bottom surface of the semiconductor chip (C) in order to minimize the occurrence of problems such as flux application defect, alignment failure, bonding failure, etc. by unfolding the semiconductor chip transformed by preheating with a laser as flat as possible in a process of flux dipping or position alignment or bonding by picking up the semiconductor chip with an adsorption type bonding tool in a laser compression bonding process, and which bonds the semiconductor chip (C) to a substrate (P) by irradiating a laser beam (L) from a laser generator (20) installed in the upper part of the bonding tool (10) while placing and pressing the semiconductor chip on the substrate P after aligning the position with the substrate (P), wherein the laser generator (20) preheats the semiconductor chip (10) at a predetermined temperature in order to restore the semiconductor chip (10) to an original flat state while the bonding tool (10) adsorbs the semiconductor chip (C).

### TECHNICAL FIELD OF THE INVENTION

According to the present invention, during the process of picking up a semiconductor chip with a vacuum adsorption bonding tool and performing flux dipping or position alignment and bonding with a substrate in a laser pressing and bonding process, a bonding laser generator preheats the semiconductor chip to a predetermined temperature and restores the deformed semiconductor chip such as warping or warpage to the original state as flat as possible, thereby minimizing problems such as poor application of flux to bumps on the bottom surface of the semiconductor chip, poor position alignment with the semiconductor chip, and poor bonding.

### BACKGROUND OF THE INVENTION

In general, a flip chip bonding process is performed by passing a bump structure called lead-free solder or Cu pillar through a convection reflow. In the reflow structure, the substrate and semiconductor chip are heated simultaneously, which can cause unwanted problems. This causes a phenomenon in which a bump or a microscopic circuit layer of the semiconductor chip is damaged due to a difference in thermal expansion coefficient between the semiconductor chip and the substrate, and the most serious problem is that bonding is not normally performed due to warpage of the semiconductor chip, resulting in a defect.

If any of the thousands to tens of thousands of bumps are not soldered well, a package function may be problematic, so a lot of efforts have been made to prevent the bumps from being damaged while passing through the reflow.

In order to solve this problem, laser assisted bonding technology has been studied. In general, while the time passing through the reflow is about 5 to 7 minutes, laser assisted bonding using laser technology applies heat to only the chip portion for a very short time of 1 to 5 seconds per area to bond. Therefore, a high temperature is maintained only in the semiconductor chip and the periphery, and the temperature is relatively low in the other regions. Since the time of exposure to heat is short and the region is local, thermal stress generated in the semiconductor chip and the bump is relatively low. In addition, laser assisted bonding is excellent in terms of space utilization because it is about 1/7 smaller than the existing convection reflow facility.

In addition, in order to integrate a semiconductor IC and diversify functions in recent years, since a large number of terminals (bump pads) should be formed in one semiconductor chip, a pitch between terminals is narrowed, and a substrate and a semiconductor chip are also undergoing changes in order to meet the trend of weight reduction and multifunctionality. Film-type substrates are being utilized, and as the thickness of the chip is reduced to be suitable for high-density mounting, the bonding area is increasing, and the application rate of the 2.5D/3D package is increasing.

Meanwhile, if bonding is performed by irradiating only a laser without pressing a semiconductor chip, even if heat is applied in a short time, a defect may occur even by a small curve. Even if heat is locally applied in a short time, if the semiconductor chip is not precisely pressed, quality deterioration due to bending of the substrate and the chip is caused.

For this reason, a bonding tool capable of pressing the semiconductor chip while transmitting the laser is required. The semiconductor chip absorbs energy oscillated from the laser, and at the same time, the temperature rises rapidly, and the semiconductor chip should be able to smooth the curve with the semiconductor chip by vacuum adsorption and pressing function to hold the twist and curve. In addition, the bonding tool should have a very good laser transmittance.

In addition, since the semiconductor chip is very thin and has different thermal expansion (thermal contraction) characteristics of several materials forming numerous layers constituting the inside thereof and different expansion rates for each material due to changes in ambient temperature, warpage occurs, causing the semiconductor chip to become twisted or bent rather than remaining flat.

Due to this warpage, conventionally, as shown in FIG. 6, in a state in which the vacuum adsorption type bonding tool 1 for laser bonding adsorbs the semiconductor chip 2, an outer portion of the semiconductor chip 2 droops downward or other lower surface of the semiconductor chip 2 does not form a flat state, and as a result, in a process of dipping the container V containing the flux F and applying the flux to the bump on the lower surface of the semiconductor chip, a problem occurs in that the flux F is not applied to all of the bumps formed on the lower surface of the semiconductor chip 2 and the flux is applied only to some bumps (outer portion in the drawing) and the flux is not applied to the inner bumps as shown in the photograph of FIG. 7, resulting in a laser bonding defect, and in an inspection area for position alignment, camera focusing due to warpage of the semiconductor chip is performed only in some areas and the remaining parts are not properly performed, resulting in incomplete alignment, which causes a bonding defect with the substrate even when the laser bonding process is performed.

In order to solve this problem, a conventional method of seating a semiconductor chip on a heating table and preheating a flip chip using conduction heat generated by a heater has been suggested, but the conventional method of preheating using conduction heat of a heater as described above takes an excessive time to raise the temperature to the desired preheating temperature, and even after preheating, uniform temperature distribution over the entire area of the flip chip is not achieved, and thus, the flip chip is not completely restored to its original flat shape, so that bonding failure as described above still occurs.

### Prior Art

### Patent Document

(Patent Document 0001) Korean Patent No. 10-1788021 (2017.10.13.)

(Patent Document 0002) Korean Patent No. 10-2235493 (2021.03.29.)

(Patent Document 0003) Korean Patent Laid-Open No. 10-2021-0052774 (2021.05.11.)

(Patent Document 0004) Korean Patent No. 10-2147681 (2020.08.19.)

(Patent Document 0005) Korean Patent No. 10-2363436 (2022.02.10.)

### SUMMARY OF THE INVENTION

### Problem to be Solved

The present invention has been devised to solve the above problems, and an object of the present invention is to minimize problems such as flux application failure that may occur in the flux application process, positional alignment failure due to forklift failure in the process of aligning the bonding position with the substrate, bonding failure with the substrate, and the like that may occur in the process of applying the flux by picking up a semiconductor chip with a vacuum adsorption bonding tool in the semiconductor chip bonding process using a laser to apply the flux in a flux dipping zone, preheating the semiconductor chip to a predetermined temperature using a heat source for laser bonding instead of using a heating table in the process of bonding the semiconductor chip to the substrate, and unfolding the semiconductor chip deformed such as warping or bending to the original shape as flat as possible in the process of bonding the semiconductor chip to the substrate.

### Solution to Problem

According to an aspect of the present invention, there is provided a laser compression bonding process in which a semiconductor chip is bonded to a substrate by adsorbing the semiconductor chip using a bonding tool to apply a flux to a bump, aligning a position with the substrate, placing the semiconductor chip on the substrate and pressing the semiconductor chip while irradiating a laser beam from a laser generator installed above the bonding tool.

The laser generator adds a step of preheating the semiconductor chip at a predetermined temperature to restore the semiconductor chip to an original flat state while the bonding tool absorbs the semiconductor chip, thereby preventing welding defects in a flux application and laser bonding process, thereby providing a chip deformation control method in the laser compression bonding process.

In a preferred embodiment, the preheating of the semiconductor chip by the laser generator is performed in the process of moving each process before the process of applying the flux to the bump on the bottom surface of the semiconductor chip, the process of aligning the position with the substrate, and the laser bonding process with the substrate, so that the occurrence of defects in each process, that is, the deterioration of the accuracy of the position alignment inspection due to the flux application defect and the focusing defect, and the bonding defect with the substrate may be minimized, and the temperature for preheating the semiconductor chip may be set differently depending on the warpage characteristics of the semiconductor chip.

### Effect of Invention

According to the above-described embodiment of the present invention, since preheating is performed at a uniform temperature over the entire area of the semiconductor chip within a very short time compared to a method of controlling warpage of the semiconductor chip by preheating in a heating table of the related art, the semiconductor chip is restored to an original flat state and bonding defects in a laser bonding process after a process of applying flux and a process of inspecting alignment warpage with a substrate are prevented in a state in which a bonding tool is stably adsorbed, and the problem of requiring a separate heating table as in the related art is solved, which promotes equipment simplification and provides beneficial effects of shortened preheating time through laser irradiation and improved bonding quality.

### BRIEF DESCRIPTION OF THE DRAWINGS

FIG. 1 is a schematic structural view of a laser compression bonding apparatus;

FIG. 2 is a view for describing a chip warpage control method in a laser compression bonding process according to the present disclosure.

FIG. 3 is a photograph showing a gripping state of a semiconductor chip before and after preheating by a laser generator.

FIG. 4 is a photograph showing a camera focusing state for alignment of a semiconductor chip showing states before and after preheating by a laser generator.

FIG. 5 is a bottom photograph of a semiconductor chip showing a flux coating state of the semiconductor chip after being preheated by a laser generator.

FIG. 6 is a front view illustrating a state in which a semiconductor chip deformed in a conventional laser bonding apparatus is picked up by a pickup tool and flux is applied.

FIG. 7 is a photograph of a bottom surface of the semiconductor chip in a state in which flux is applied in the state of FIG. 6.

### DETAILED DESCRIPTION OF THE DRAWINGS

Hereinafter, preferred embodiments that do not limit the present invention will be described in detail with reference to the accompanying drawings.

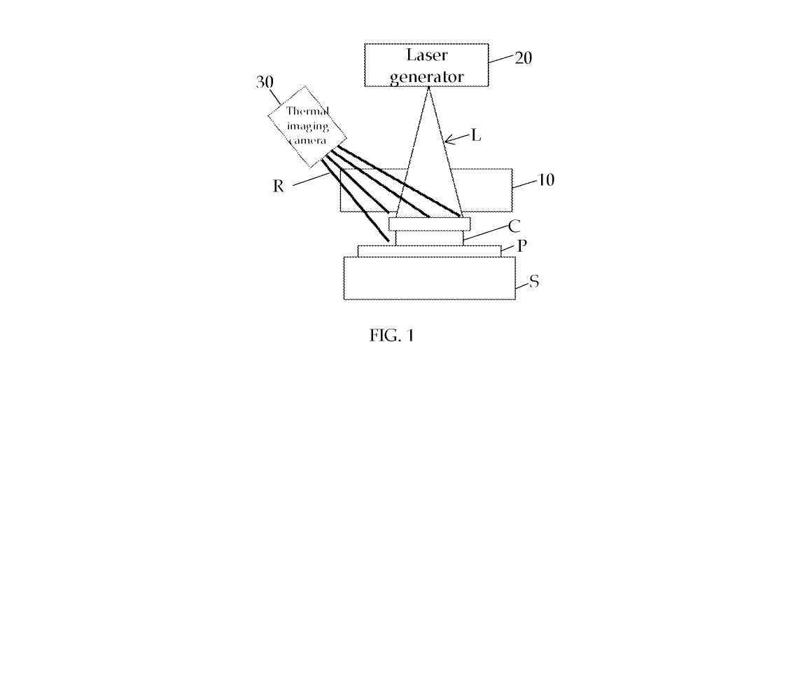

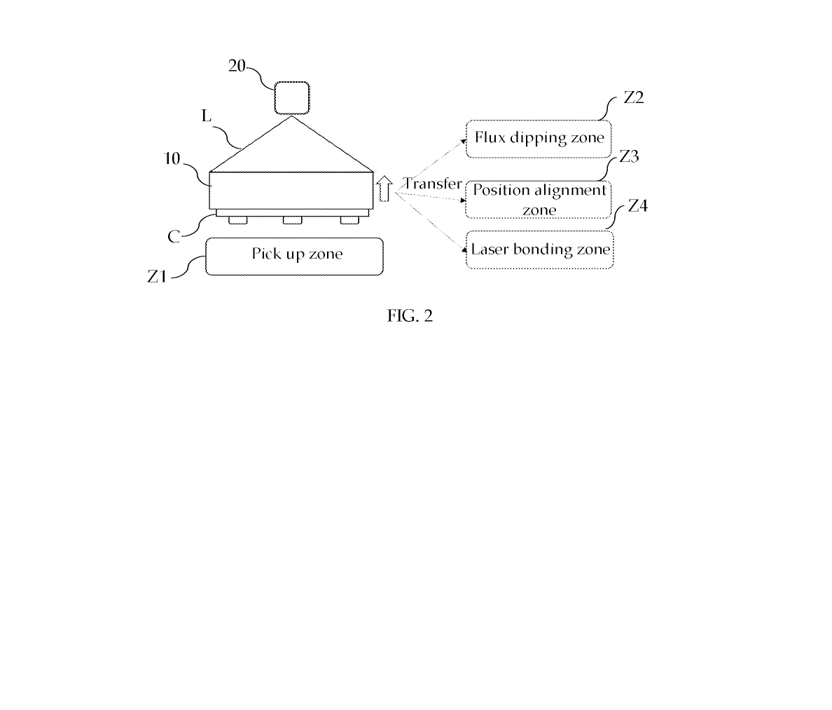

FIG. 1 is a schematic structure of a laser compression bonding apparatus to which a chip warpage control method according to the present invention is applied, and FIG. 2 schematically illustrates a state in which laser irradiation for preheating is performed from a laser generator on a semiconductor chip adsorbed to a bonding tool of a laser bonding apparatus, and a process transfer state to a flux dipping zone, a position alignment zone, and a bonding zone in a state in which preheating is performed.

As could be seen from FIGS. 1 and 2, the present invention is directed to a laser compression bonding process in which a semiconductor chip C is adsorbed and picked up by a bonding tool 10 in a pickup zone Z1 to apply a flux to a bump on the bottom surface of the semiconductor chip C in a flux dipping zone Z2, a position with a substrate P is aligned by a vision camera in a position alignment zone Z3, and then the semiconductor chip C is bonded to the substrate P by irradiating a laser beam L from a laser generator 20 installed on the top of the bonding tool 10 while placing and pressing the substrate P in a bonding zone Z4.

The laser generator 20 preheats the semiconductor chip 10 to a predetermined temperature in a state in which the semiconductor chip C is adsorbed to restore the semiconductor chip 10 to an original flat state, thereby preventing welding defects in a flux application process, a position alignment with a substrate, and a laser bonding process.

Meanwhile, as schematically shown in FIG. 1, the laser pressing bonding apparatus basically includes a bonding tool 10 for sucking and fixing a semiconductor chip C in a vacuum and then placing and pressing the semiconductor chip C on a substrate P, a laser generator 20 installed above the bonding tool 10 to irradiate a laser beam L for bonding between the semiconductor chip C and the substrate P, and a non-contact thermometer 30 (thermal imaging camera) for monitoring a temperature of a surface of the semiconductor chip C.

In addition, the substrate P is fixed to a lower chuck S, and the chuck S also fixes the substrate P in a vacuum adsorption method and preheats the substrate P to a predetermined temperature.

In the present invention, when the infrared thermometer or pyrometer is applied, the non-contact thermometer 30 may accurately measure the surface temperature of the semiconductor chip in real time by allowing the wavelength of the laser L oscillating during preheating and bonding and the infrared ray R emitted from the semiconductor chip C to simultaneously pass through the bonding tool 10 and reach the camera.

In the chip warpage control method in a laser pressing bonding process according to the present invention, as in the conventional laser pressing bonding apparatus, a semiconductor chip and a substrate are introduced into a bonding zone from a pre-bonding zone via a conveyor unit, laser pressing bonding is performed thereon, and then sequentially transferred to an unloader zone.

In the present invention, as illustrated in FIG. 2, in a state in which the bonding tool 10 ascends in a state of picking up the semiconductor chip C and the laser L for preheating in the laser generator 20 in the air passes through the bonding tool 10 and is irradiated to the semiconductor chip C to restore the semiconductor chip C to a flat state, flux dipping, position alignment by a vision camera, and a laser bonding process to the substrate C are performed.

In the present disclosure, the temperature for preheating the semiconductor chip C, that is, the surface temperature of the semiconductor chip C detected by the thermometer 30 is different depending on the warpage characteristics of the semiconductor chip C, and for example, when the warpage of the semiconductor chip C is at a minimum of 100°C., the laser beam irradiation intensity of the laser generator 20 may be set in consideration of the reference time of one bonding cycle, and the warpage characteristics of the semiconductor chip C are different depending on the manufacturer or other materials of the semiconductor chip, and thus, the preheating temperature may be appropriately set by receiving data on the warpage characteristics.

In the present invention, preheating is performed by a laser generator while the bonding tool moves for flux coating, position alignment, and laser bonding as described above while adsorbing the semiconductor chip, additional time consumption for preheating is not generated, so that laser bonding time could be reduced. Also, since preheating is performed by using the laser generator which is a heat source for main bonding without using a separate preheating means such as a heating table, the configuration of equipment is also simple. In contrast to using conductive heat by a heating table, rapid and uniform preheating is possible over the entire area of the semiconductor chip, so that the semiconductor chip could be restored to the original flat state. This provides the advantage of minimizing defects in flux application, alignment accuracy defects due to focusing problems during position alignment by vision cameras, and bonding defects with the substrate by laser.

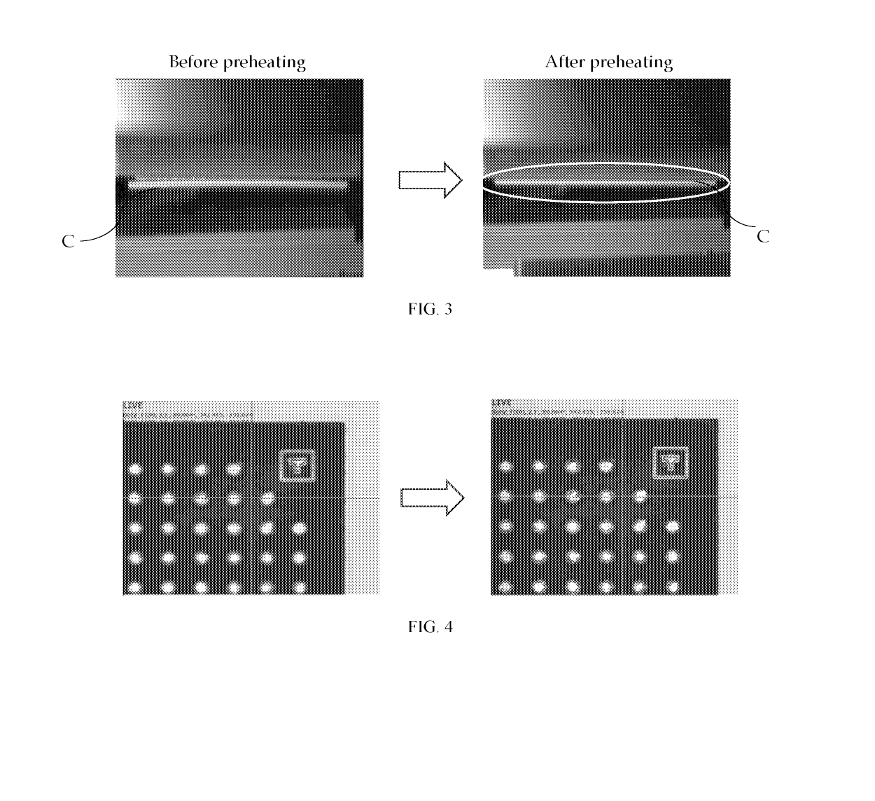

FIG. 3 is a photograph of the semiconductor chip C adsorbed to the bonding tool BD showing a state before and after preheating by the laser generator in the method for controlling chip warpage according to the present invention, and unlike the case in which the semiconductor chip C is adsorbed to the bottom surface of the adsorption-type bonding tool 10 as shown in the left photograph before preheating but the flatness thereof is reduced, it could be confirmed that when the semiconductor chip C is preheated by laser irradiation by the laser generator 20, the semiconductor chip C is restored to its original state to be flat as shown in the right photograph and the gripping force by the bonding tool 10 is increased.

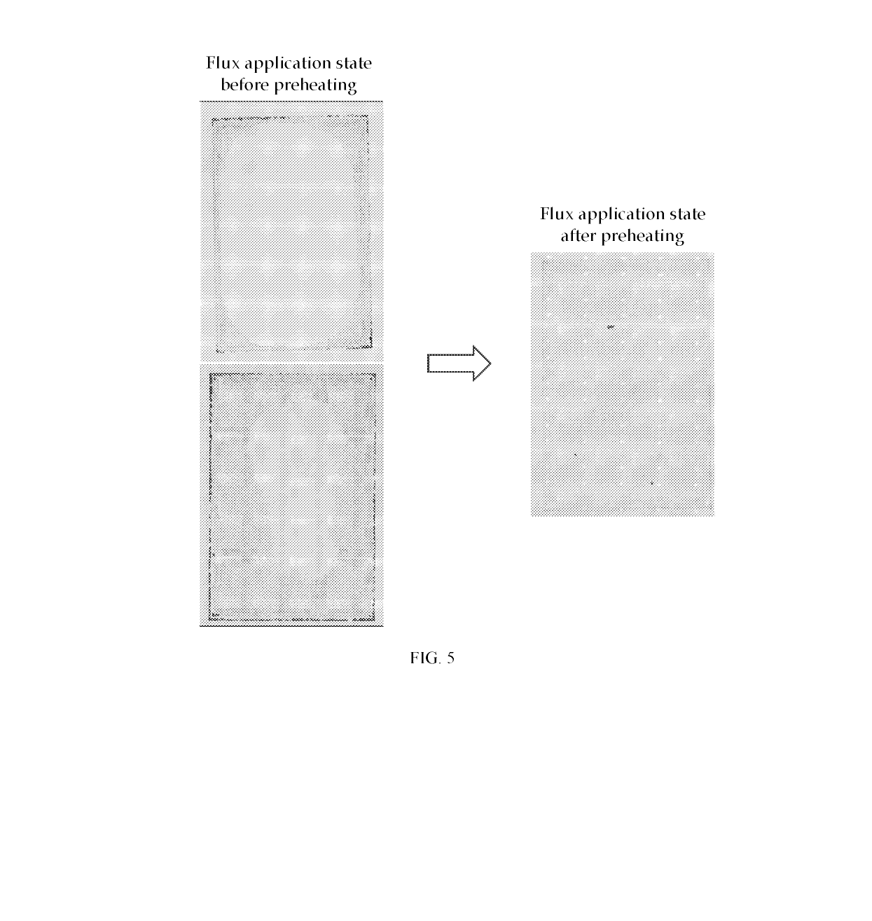

In addition, FIG. 4 is a photograph showing a camera focusing state for aligning a semiconductor chip showing a state before and after preheating by a laser generator in the chip warpage control method of the present invention, in which, when camera focusing is performed in a state in which preheating is not performed, that is, in a state in which there is a warpage as shown in FIG. 3, some areas are focused but focusing is not completely performed at an outer side, such that accuracy of position alignment by a vision camera is deteriorated, but when preheating is performed by laser irradiation by a laser generator 20, the semiconductor chip C is flatly restored to an original state as shown in a photograph of a right side, such that focusing by a vision camera is uniformly performed as a whole, thereby improving accuracy of position alignment by the vision camera.

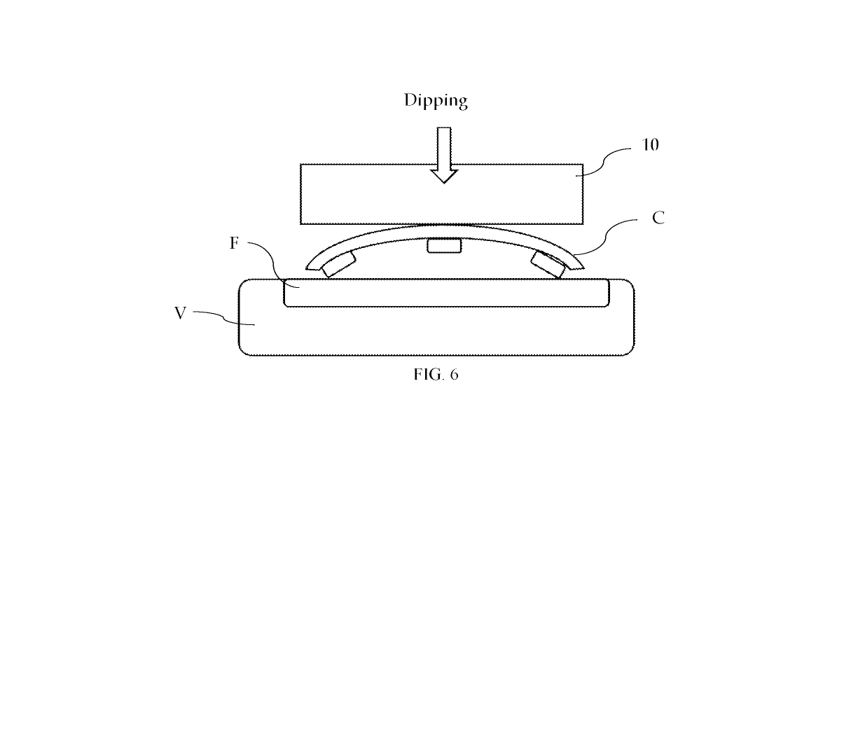

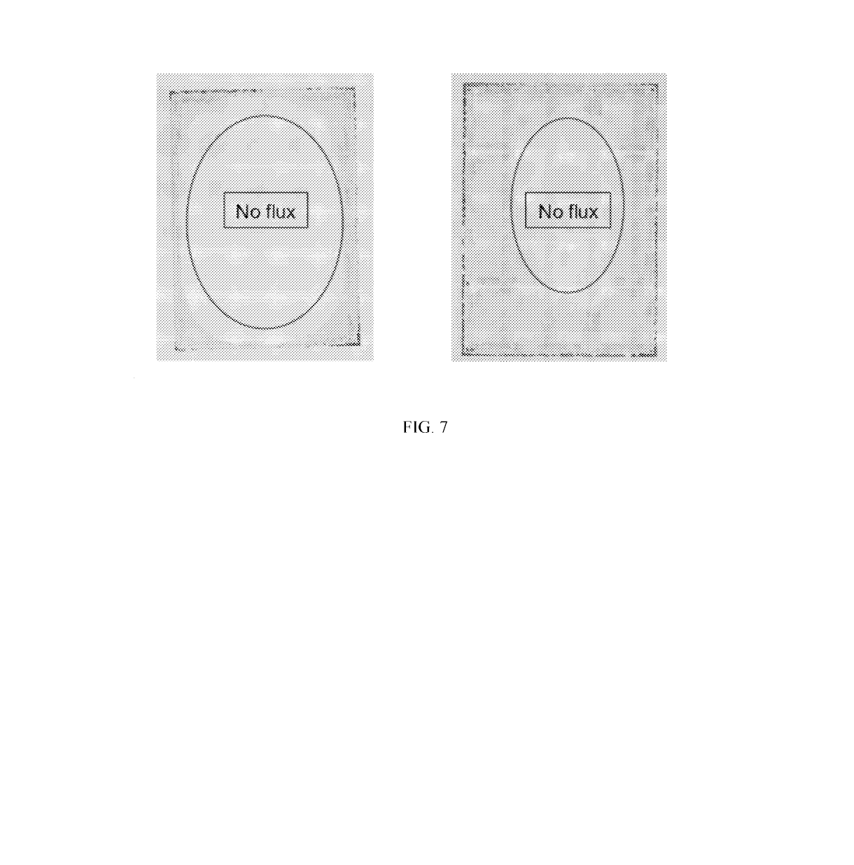

In addition, in the chip warpage control method of the present invention, compared to the left photograph of FIG. 5, as illustrated in the right photograph, the bottom surface of the semiconductor chip C is restored to a flat state after being preheated by the laser generator, and thus, a state in which the flux is uniformly applied to the bumps over the entire bottom surface of the semiconductor chip is shown, and thus it may be confirmed that a defect in the flux application may be prevented by preheating the semiconductor chip, thereby minimizing a welding defect during laser bonding with the substrate.

As described above, according to the chip warpage control method in a laser compression bonding process according to the present invention, it is possible to improve bonding quality by performing preheating during the process in a state in which the semiconductor chip is adsorbed to the bonding tool using the laser generator used for laser bonding without using a separate heat source such as a heating table to flatly restore the deformed semiconductor chip to the original state without wasting time, and performing flux coating, position alignment, and bonding.

### DESCRIPTION OF SYMBOLS

10: bonding tool

20: laser generator

30: Thermometer

C: semiconductor chip

F: flux

L: laser (beam)

P: substrate

R: infrared

S: chuck

V: container

Z1: Pick up zone

Z2: flux dipping zone

Z3: position alignment zone

Z4: bonding zone

What is claimed is:

1. A chip warpage control method in a laser pressing bonding process, the method comprising: adsorbing a semiconductor chip (C) using a bonding tool (10) to apply a flux to a bump on a bottom surface of the semiconductor chip (C); aligning a position of the semiconductor chip (C) with a substrate (P); and placing the semiconductor chip (C) on the substrate (P)and pressing the substrate (P); wherein the semiconductor chip (C) is bonded to the substrate (P) by irradiating a laser beam (L) from a laser generator (20) installed on an upper portion of the bonding tool (10), and the method comprises preheating the semiconductor chip (C) at a predetermined temperature such that the semiconductor chip (10) is restored to an original flat state in a state in which the bonding tool (10) adsorbs the semiconductor chip (C).

2. The chip warpage control method in a laser pressing bonding process of claim 1, wherein the preheating of the semiconductor chip (C) by the laser generator (20) is performed before a process of applying a flux to a bump on a bottom surface of the semiconductor chip, a position alignment process with the substrate, and a laser bonding process with the substrate.

3. The chip warpage control method in a laser pressing bonding process of claim 1, wherein a temperature for preheating the semiconductor chip (C) is set differently according to warpage characteristics of the semiconductor chip (C).
